(19) United States
(12) Patent Application Publication
(10) Pub. No.: US 2009/0325329 A1
(43) Pub. Date: Dec. 31, 2009

(54) METHOD FOR MANUFACTURING ELECTRON EMITTING DEVICE AND MEMORY MEDIUM OR RECORDING MEDIUM THEREFOR

(75) Inventor: Masaki Kuribayashi, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/369,478

(22) Filed: Feb. 11, 2009

Related U.S. Application Data
(63) Continuation of application No. PCT/JP2008/061751, filed on Jun. 27, 2008.

(51) Int. Cl. H01J 9/00; H01L 21/02; G06F 19/00

(52) U.S. Cl. 438/20; 700/121; 257/E21.002

(57) ABSTRACT

A method and an apparatus for manufacturing a high intensity electron emitting device using a boron lanthanum compound thin film are provided. Sputtered particles of a low work function substance target are accumulated on a second substrate disposed an electron emitting base member. By using a mask for screening the electron emitting base member region opening other regions, the deposition of a low work function substance on the second substrate is etched, and after that, the second substrate and the first substrate disposed with the phosphor are sealed by a sealing agent to fabricate a vacuum chamber. During the fabrication step thereof, the first and second substrates are consistently maintained in a vacuum atmosphere or a reduced pressure.

### CROSS-REFERENCES TO RELATED APPLICATIONS

This application is a continuation application of International Application No. PCT/JP2008/061751, filed on Jun. 27, 2008, the entire contents of which are incorporated by reference herein.

### TECHNICAL FIELD

The present invention relates to a method for manufacturing a crystalline electron emitting device by a sputtering method using a target having the sintered body of a low work function substance, in particular a boron lanthanum compound, and a computer memory medium or a recording medium thereof.

### BACKGROUND ART

As disclosed in Patent Documents 1, 2, and 3, as a secondary electron emission film, a thin film of a boron lanthanum compound such as LaB₆ is known. Further, as disclosed in Patent Documents 1, 2, and 3, it is also known that the crystalline thin film of a boron lanthanum compound is deposited by using the sputtering method. Further, as disclosed in Patent Document 4, it is also known that, as a target used by the sputtering method, a sintered body of the boron lanthanum compound such as LaB₆ is used.

Patent Document 1: Japanese Patent Application Laid-Open No. H1-286228

Patent Document 2: Japanese Patent Application Laid-Open No. H3-232959

Patent Document 3: Japanese Patent Application Laid-Open No. H3-101033

Patent Document 4: Japanese Patent Application Laid-Open No. H6-248446

### DISCLOSURE OF THE INVENTION

However, when a boron lanthanum compound thin film is exposed to the atmosphere after the deposition by a sputtering apparatus, it is oxidized. When this oxidized boron lanthanum compound thin film is used for the electron emitting device such as a FED (Field Emission Display) and a SED (Surface-Conduction Electron-emitter Display), it has been hard to obtain sufficient luminance as a display device.

An object of the present invention is to provide an electron emitting device having sufficient luminance using a boron lanthanum compound thin film.

The first aspect of the present invention is a manufacturing method of an electron emitting device, comprising: a first step of preparing a first substrate disposed with phosphors and disposing the first substrate in a vacuum or reduced pressure atmosphere; a second step of disposing an electron emitting base member on a second substrate; a third step of accumulating sputtered particles on the second substrate subjected to said second step by a sputtering method using a target having a low work function substance inside a vacuum or reduced pressure atmosphere; a fourth step of disposing a mask for screening a first region including said electron emitting base member and opening a second region not including said electron emitting base member, in a state in which a vacuum or reduced pressure atmosphere is maintained from said third step; a fifth step of etching a deposition of a low work function substance on the second substrate subjected to said fourth step, in a state in which the vacuum or reduced pressure atmosphere is maintained from said fourth step; and a sixth step of making the first substrate subjected to said first step opposed to the second substrate subjected to said fifth step and sealing the first substrate and the second substrate by a sealing agent to fabricate a vacuum or reduced pressure chamber, in a state in which the vacuum or reduced pressure atmosphere is maintained from said first step and said fifth step.

The second aspect of the present invention is a memory medium or a recording medium for the manufacturing of an electron emitting device, comprising a control program for executing: a first step of preparing a first substrate disposed with phosphors and disposing the first substrate in a vacuum or reduced pressure atmosphere; a second step of disposing an electron emitting base member on a second substrate; a third step of accumulating sputtered particles on the second substrate subjected to said second step by a sputtering method using a target having a low work function substance inside a vacuum or reduced pressure atmosphere; a fourth step of disposing a mask for screening a first region including said electron emitting base member and opening a second region not including said electron emitting base member, in a state in which a vacuum or reduced pressure atmosphere is maintained from said third step; a fifth step of etching a deposition of the low work function substance on the second substrate subjected to said fourth step, in a state in which the vacuum or reduced pressure atmosphere is maintained from said fourth step; and a sixth of making the first substrate subject to said first step opposed to the second substrate subjected to said fifth step and sealing the first substrate and the second substrate by a sealing agent to fabricate a vacuum or reduced pressure chamber, in a state in which the vacuum or reduced pressure atmosphere is maintained from said first step and said fifth step.

According to the present invention, the crystalline thin film of a boron lanthanum compound such as LaB₆ can be sealed in a vacuum chamber without being oxidized, thereby a display device having high luminance can be realized.

### BRIEF DESCRIPTION OF THE DRAWING

FIG. 1 is a schematic illustration showing a first example of a magnetron sputtering apparatus used for a manufacturing method of a thin film of the present invention;

FIG. 2 is a schematic sectional view of an electron generator of the present invention;

FIG. 3 is a flowchart of the present invention;

FIG. 4 is a block diagram of the present invention;

FIG. 5A is a sectional view of a mask fabrication step using an ink jet device of the present invention;

FIG. 5B is a sectional view of a mask fabrication step using an ink jet device of the present invention; and

FIG. 6 is a schematic perspective view of an electron emitting device obtained by the manufacturing method of the present invention.

### DESCRIPTION OF SYMBOLS

1 First Chamber
2 Second Chamber
5, 51, 52, 53, 54, 55 Gate Valve
11 Target
12 Substrate
13, 15, 42, 43 Substrate Holder
14 Sputter Gas Introducing System
16 Heating Mechanism
17 Plasma Electrode
18 Plasma Source Gas Introducing System
19 Sputtering High Frequency Power Source System
191, 221, 502 Blocking Capacitor
192, 222, 503 Matching Circuit
193, 223, 504 High Frequency Power Source
194 Sputtering DC Power Source (First DC Bias Power Source)
20 (Annealing) Substrate Bias Power Source (Third DC Power Source)
21 Substrate Bias Power Source (Second DC Power Source)
22 Plasma Source High Frequency Power Source System
23, 501 LF Cut Filter for cutting LF components from HF Power Source 193
24 HF Cut Filter
101 Cathode
102 Magnetic Field Generator
103 Magnetic Field Region
201, 207 Glass Substrate
202 Cathode Electrode
203 LaB₆ Thin Film
204 Vacuum Space
205 Anode Electrode
206 Phosphor Film
208 Electron Source Substrate
209 Projection
210 Phosphor Substrate
211 DC Power Source
401 Magnetron Sputtering Apparatus
402 First Gate Valve
403 Vacuum Ink Jet Device
404 Second Gate Valve
405 Dry Etching Device
406 Third Gate Valve
407 Assemble Device in Vacuum Space
408 Fourth Gate Valve
409 Device for Transferring Phosphor Substrate into Vacuum Atmosphere
410 Computer
411 Arithmetic Operation Circuit Unit
412, 413, 414, 415, 416, 417, 418, 419, 426 427, 428, 429 Control Bus Line
420 Memory Unit
421 Time Control Unit
422 First Load Lock Chamber
423 Fifth Gate Valve
424 Second Load Lock Chamber
425 Sixth Gate Valve
51 Ink Jet Device
52 Droplet
53 Mask
601 Display-Side Substrate
602 Three Primary Color Phosphor Matrix
603 Black Matrix
604 Anode Electrode
605 Spacer
606 Rear Face Substrate
607 Insulator Film
608 Scan Line
609 Signal Line
610 Hole containing Electron Emitting Device inside thereof

### BEST MODES FOR CARRYING OUT THE INVENTION

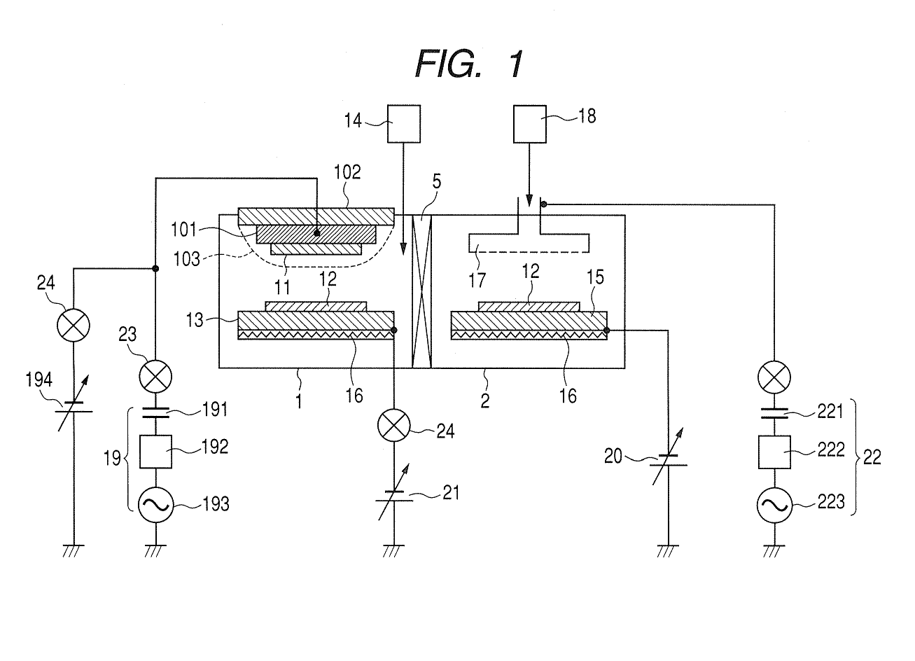

FIG. 1 is a schematic illustration showing a first example of a magnetron sputtering apparatus used in the manufacturing method of a thin film of the present invention. Reference numeral 1 denotes a first chamber, reference numeral 2 a second chamber (annealing unit) connected in vacuum to the first chamber 1, reference numeral 5 a gate valve, reference numeral 11 a sputtering target, reference numeral 12 a substrate, reference numeral 13 a substrate holder (first substrate holder) for holding the substrate 12, reference numeral 14 a sputter gas introducing system, reference numeral 15 a substrate holder (second substrate holder), reference numeral 16 a heating mechanism, reference numeral 17 a plasma electrode, reference numeral 18 a plasma source gas introducing system, reference numeral 19 a sputtering high frequency power source system, reference numeral 101 a cathode loadable with the target 11, reference numeral 102 a magnetic field generator, reference numeral 103 a magnetic field region, reference numeral 191 a blocking capacitor, reference numeral 192 a matching circuit, reference numeral 193 a high frequency power source, reference numeral 194 a sputter bias power source, reference numeral 20 a (annealing) substrate bias power source (third DC power source), reference numeral 21 a substrate bias power source (second DC power source), reference numeral 22 a plasma source high frequency power source system, reference numeral 221 a blocking capacitor, reference numeral 222 a matching circuit, reference numeral 223 a high frequency power source, and reference numeral 23 an LF cut filter (filter) for cutting the LF components from the HF power source 193 so as to be turned into an HF component power. Reference numeral 24 denotes a HF cut filter for cutting the HF components (for example, HF components such as 1 KHz or more, particularly like 1 MHz) contained in the DC power from the DC power sources 21 and 194.

In the present invention, the target 11 containing a boron atom (B) and a lanthanum atom (La) such as LaB₆ is used.

The substrate 12 is placed on the holder 13 inside the first chamber 1, and the substrate 12 is opposed to the cathode 101, and is subjected to vacuum exhaust and heating (increased up to the temperature of the sputtering time later) inside the chamber. The heating is executed by the heating mechanism 16. Next, a plasma source gas (helium gas, argon gas, krypton gas, xenon gas) is introduced from the sputtering gas introducing system 14, and is set to the predetermined pressure (0.01 Pa to 50 Pa, and preferably 0.1 Pa to 10 Pa), and after that, a deposition is started by using the sputter power source 19.

Next, by applying a high frequency power from a high frequency power source 193 (the frequency is 0.1 MHz to 10 GHz, and preferably 1 MHz to 5 GHz, and the input power is 100 W to 3000 W, and preferably 200 W to 2000 W), plasma is generated, and in the first DC power source 194, a DC power (voltage) is set to the predetermined voltage (−50 V to −1000 V, and preferably −10 V to −500 V), thereby to perform a sputter deposition. At the substrate 12 side, the DC power (voltage) is applied to the substrate holder 13 with the predetermined voltage (0 V to −500 V, and preferably −10 V to −100 V) by the second DC power source 21. The DC power (first DC power) from the first DC power source 194 may be inputted before applying the high frequency power from the high frequency power source 193, and may be inputted simultaneously with the application of the high frequency power, and may be continuously inputted after completing the application of the high frequency power.

An input position to the cathode 101 of the DC power and/or the high frequency power from the second DC power source 21 and/or the sputtering high frequency power source 19 is preferably set to a plurality of points symmetrical to the center point of the cathode 101. For example, the position symmetrical to the center point of the cathode 101 may be set to a plurality of input positions of the DC power and/or the high frequency power.

The magnetic field generator 102 formed by a permanent magnet and an electromagnet is located and disposed at the rear of the cathode 101, and can expose the surface of the target 11 to a magnetic field 103. While the magnetic field 103 preferably does not reach up to the surface of the substrate 12, if it is to the extent of not narrowing an extensive single-crystal domain of the boron lanthanum compound, the magnetic field 103 may reach the surface of the substrate 12.

An HF cut filter 24 provided at the side of the first DC power source 194 used in the present invention can protect the first DC power source 194 as another effect.

A south pole and a north pole of the magnetic field generating means 102 can be mutually disposed as an opposite polarity in a vertical direction to the flat surface of the cathode 103. At this time, adjacent magnets are made mutually into an opposite polarity in a horizontal direction to the flat surface of the cathode 103. Further, the south pole and the north pole of the magnetic field generating means 102 can also be mutually disposed as an opposite polarity in the horizontal direction to the flat surface of the cathode 103. At this time also, the adjacent magnets are mutually made into an opposite polarity in the horizontal direction to the flat surface of the cathode 103.

In the preferred aspect of the present invention, the magnetic field generating means 102 can perform an reciprocation motion in the horizontal direction to the cathode 101 or the surface of the target 11.

The filter 23 used in the present invention can cut a low frequency component (0.01 MHz or less, particularly, the frequency component 0.001 MHz or less) from the high frequency power source 193.

Further, the present invention can extend an average area of the single-crystal domain by applying the DC power (voltage) from the second DC power source 21 of the substrate 12 side to the substrate holder 13. This second DC power (voltage) may be a pulse waveform power having a DC component (DC component to the ground) in an hourly average.

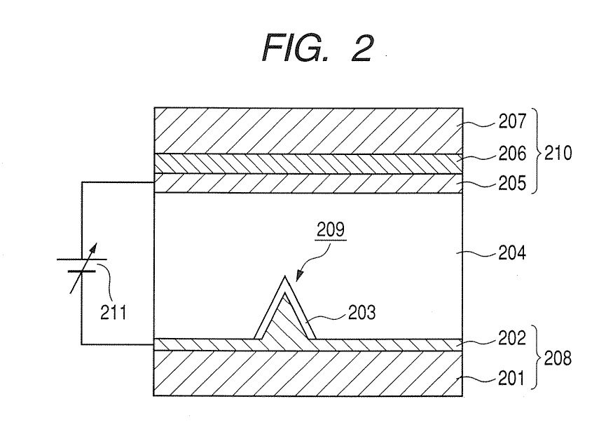

In FIG. 2, reference numeral 208 denotes an electron source substrate having a molybdenum film (cathode electrode) 202 formed a cone-shaped projection 209 (spindt-type electron emitting base member), and a LaB₆ film 203 coating the projection 209 of the molybdenum film. Reference numeral 210 denotes a phosphor substrate made of a glass substrate 207, a phosphor film 206 thereon, and an anode electrode 204 made of a thin aluminum film. A space 204 between these electron source substrate 208 and phosphor substrate 210 is a vacuum space. By applying a DC voltage of 100 V to 3000 V between the cathode electrode 202 and an anode electrode 205, an electron beam is irradiated from the top end of the projection 209 of the molybdenum film 202 coated by the LaB₆ film 203 to the anode electrode 205, and the electron beam transmits the anode electrode 205, and there, it collides against the phosphor film, so that the phosphor can be made to emit light.

In the present invention, as the electron emitting base member, it is not limited to the above described, and in addition, it may be a SED type electron emitting base member using the thin film (PdO thin film, crystal carbon thin film, and the like) forming a nano scale gap by a forming process.

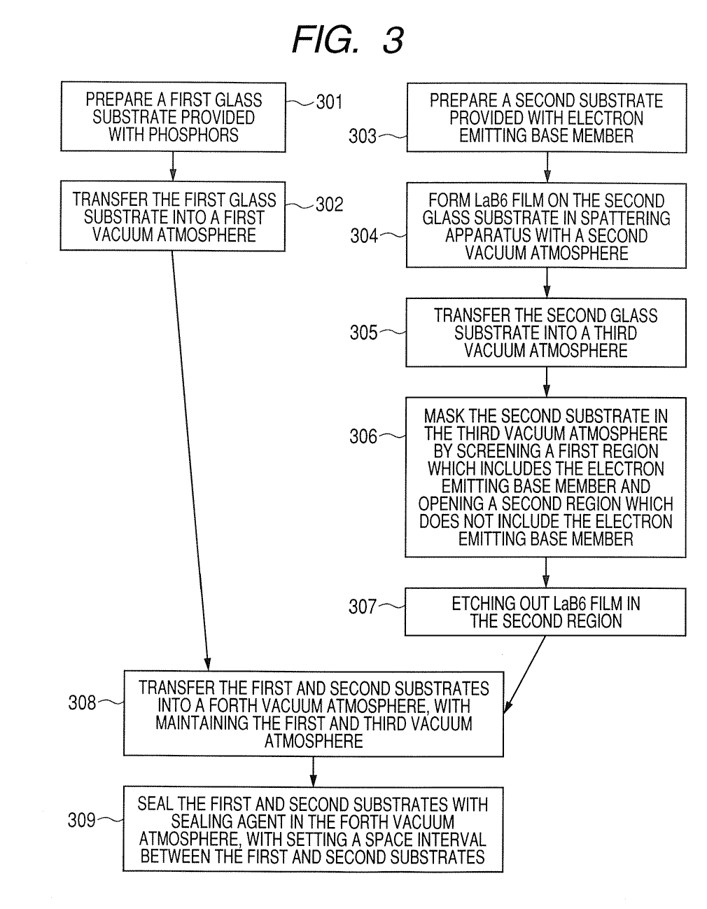

FIG. 3 is a view showing a flowchart of the present invention. A step 301 is a step to prepare a first glass substrate provided with a phosphor film which emits a phosphor light when an irradiation of electron is received. A phosphor layer is disposed with phosphors of three kinds for emitting a red fluorescence, a green fluorescence, and a blue fluorescence. While the red phosphor, the green phosphor, and the blue phosphor are linearly disposed in the signal line direction of a matrix wiring made of the scan line and the signal line, the disposition of the phosphors is not limited to this. To the glass substrate, it is possible to dispose a conductive film (an aluminum film, a titanium film, a barium film, and the like) serving as an anode electrode for accelerating the electron from the electron source, a black matrix body (for example, a black resin matrix, a metal matrix, and the like) for partitioning the pixel, and a spacer, and the like.

A step 302 is a step in which the first glass substrate is transferred into a first vacuum chamber forming a first vacuum or reduced pressure atmosphere (hereinafter, both of “vacuum” and “reduced pressure atmosphere” are referred to as “vacuum”). At the time of transferring, an ordinary load lock chamber (not shown) and a gate valve (not shown) can be used.

A step 303 is a step in which a second glass substrate provided with the electron emitting base member is prepared. This electron emitting base member is disposed at an intersecting point with the scan line and the signal line on an equivalent circuit, and is provided for a matrix drive. While the electron emitting base member has an electron emission effect by itself, its electron emission efficiency can be improved to a large extent by the low work function substance film of the later step.

The electron emitting base member of one section together with the phosphor film of one section forms one sub-pixel. Three color pixels of one red sub-pixel, one green sub-pixel and one blue sub-pixel form one-pixel. In the present invention, the one-pixel is disposed at a plurality of columns along a plurality of rows, thereby a matrix-array can be formed. In this matrix array, a metal film wiring (aluminum wiring, copper wiring, silver wiring, and the like) for the scan line and a metal film wiring (aluminum wiring, copper wiring, silver wiring, and the like) for the signal line are formed.

Further, to the second glass substrate used in the present invention, an antistatic film (charge dissipation film) for charging an electrostatic charge generated during a manufacturing step or the operation as a display device can be preferably provided. As this antistatic film, a titanium oxide film, a tin oxide film, an indium oxide film, an indium/tin oxide film (ITO film), and the like can be used.

Further, a spacer and a sealing agent are located on the second glass substrate used in the present inventions in advance.

A step 304 is a step, in which a boron lanthanum compound film such as LaB₆ is formed on the second glass substrate by using a sputtering apparatus (magnetron sputtering apparatus, a high frequency RF magnetron sputtering apparatus, and the like shown in FIG. 1) using a second chamber of a second vacuum atmosphere. Prior to this step, the second glass substrate is transferred into the sputtering apparatus in a state in which the vacuum atmosphere is maintained by an unload lock chamber (not shown) and a gate valve (not shown).

By the step 304, the second glass substrate is formed thereon entirely or partially with the boron lanthanum compound film such as LaB₆, and as a result, the electron emitting base member is coated by the boron lanthanum compound film such as LaB₆, which is the low work function substance film.

The present invention can additionally use, for example, a CeB₆ film, a BaLaB₆ film, a carbon containing LaB₆ film, and the like as the low work function substance film.

In a step 305, the second glass substrate is transferred into a third chamber of a third vacuum atmosphere. The second chamber and the third chamber are maintained in a vacuum state by using a gate valve (not shown).

In a step 306, a first region including the electron emitting base member is screened by a mask member in the third vacuum atmosphere inside the third chamber.

In the step 306, a mask material can be coated on the LaB₆ film accumulated on the electron emitting base member, by an ink jet method. The mask material is appropriately selected from a dissoluble organic metal material, a heat-resistive organic resin material, and the like, which are slower in etching rate than LaB₆. According to need, after coating the mask material by the ink jet method, vacuum bake processing and the like can be executed. While this step 306 can be executed inside the third chamber, it may be executed in the other vacuum chambers.

A step 307 is a step in which the LaB₆ film is removed from the region not coated with the mask material (equivalent to the second region not including the electron emitting base member) by dry etching in a state in which the third vacuum atmosphere is maintained. The dry etching is preferably performed by exciting plasma under the existence of an etching gas (fluorine based gas, chlorine based gas, alcohol based gas, CO gas, oxygen gas, and the like) inside a dry etching chamber.

Further, in the step 307, it is possible to use a well-known dry etching device such as an ion beam etching apparatus and an electron beam etching apparatus.

After removing the LaB₆ film, the mask material on the electron emitting base member can be etched until the LaB₆ film on the electron emitting base member is exposed by the dry etching device, the ion beam etching apparatus, or the electron beam etching apparatus. The LaB₆ film of the second region not including the electron emitting base member becomes an unnecessary electron source for other than the pixel at the time of display, and becomes a cause of an unnecessary light emission. Consequently, when the LaB₆ film of the second region is made to remain in the display device, the display contrast is lowered, or a flickering of unnecessary light at the display unit is caused. This has been the cause of lowering the display quality. By the step 307 of the present invention, the LaB₆ film of the second region is removed, thereby the unnecessary light emission in this region is eliminated, and the display quality can be improved.

In a step 308, the first glass substrate of the step 302 and the second glass substrate of the step 307 are transferred into a fourth chamber of a fourth vacuum atmosphere, respectively, while maintaining the vacuum state. The first vacuum atmosphere, the third vacuum atmosphere, and the fourth vacuum atmosphere are vacuum-connected by a gate valve (not shown).

In a step 309, the first glass substrate and the second glass substrate are oppositely arranged at the predetermined interval inside the fourth chamber, and the position of the phosphor film of one section is accurately matched with the position of the electron emitting base member of one section so as to seal them by using the sealing agent. The predetermined interval is decided by the spacer provided in advance. The spacer may be column-like or plate-like, and is disposed at every predetermined interval. The sealing agent is provided at the first glass substrate or the second glass substrate in advance, and can seal to form a vacuum atmosphere between the first glass substrate and the second glass substrate. As the sealing agent, a low melting point metal (such as iridium and tin) and an organic resin adhesive, and the like can be preferably used.

In the step 309, the first glass substrate and the second glass substrate are held by the well-known electrostatic chuck or vacuum chuck, and in a state in which both substrates are spaced at a sufficient distance, they can be subjected to vacuum bake processing, or can be adhered with a gettering material such as barium and titan. After that, both substrates are made close up to the interval decided by the spacer material, and after that, are subjected to the sealing work processing, thereby a vacuum display panel is manufactured.

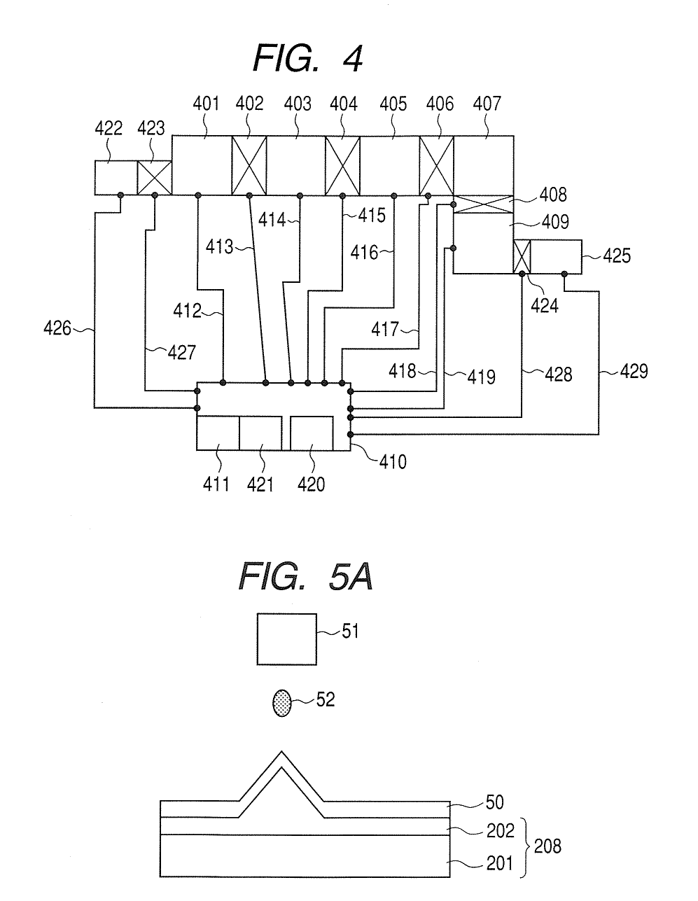

FIG. 4 is a block diagram of the present invention. Reference numeral 401 denotes a magnetron sputtering apparatus; reference numeral 402 a first gate valve, reference numeral 403 a vacuum ink jet device, reference numeral 404 a second gate valve, reference numeral 405 a dry etching device, reference numeral 406 a third gate valve, reference numeral 407 an assemble device in vacuum space, reference numeral 408 a fourth gate valve, reference numeral 409 a device for transferring phosphor substrate into vacuum atmosphere, reference numeral 410 a computer, reference numeral 411 an arithmetic operation circuit unit, reference numerals 412, 413, 414, 415, 416, 417, 418, 419, 426, 427, 428, and 429 a control bus line, reference numeral 420 a memory unit, reference numeral 421 a time control unit, reference numeral 422 a first unload lock chamber, reference numeral 423 a fifth gate valve, reference numeral 424 a second load lock chamber, and reference numeral 425 a sixth gate valve.

The first glass substrate provided with the phosphor film is transferred into the second load lock chamber 425, and after vacuum-exhausting the inside of the chamber 425, the sixth gate valve 424 is opened, and The first glass substrate is transferred into the device for transferring phosphor substrate into vacuum atmosphere 409.

The second glass substrate provided with the electron emitting base member is transferred into the first load lock chamber 422, and after vacuum-exhausting the inside of the chamber 422, the fifth gate valve 423 is opened, and The second glass substrate is positioned inside the magnetron sputtering apparatus 401. Inside this magnetron sputtering apparatus 401, the step 304 is executed.

After completing the step 304, the first gate valve 402 is opened, and the second glass substrate is transferred into the vacuum ink jet device 403. Inside the vacuum ink jet device 403, the step 306 is executed.

The dry etching device 405 can execute the step 307. The first gate valve 402, the second gate valve 404, and the third gate valve 406 perform opening and closing operations so as to maintain a vacuum state, respectively, when the second glass substrate is made to pass through the magnetron sputtering apparatus 401, the vacuum ink jet device 403, the dry etching device 405, and the assemble device in vacuum space 407 in order by a transfer robot (not shown).

Further, in the present invention, it is possible also to use a dispenser in place of the ink jet device.

The second glass substrate inside the dry etching device 405 and the first glass substrate inside the device for transferring phosphor substrate into vacuum atmosphere 409 are transferred into the assemble device in vacuum space 407, and here, the step 309 is executed.

The computer 410 has a memory unit 420, and can control all the steps from the steps 301 to 309. As the memory unit 420, it is possible to use a recording medium such as a hard disc medium, a magneto-optic disc medium, and a floppy (registered trademark) disc medium, and a non-volatile memory (memory medium) such as a flash memory and an MRAM. Further, it is possible to temporarily memorize the data from the recording medium in the memory unit 410. The memory unit 410 stores a control program for controlling all the steps from the steps 301 to 309. The stored control program data is processed by the arithmetic operation circuit unit (CPU: Central Processing Unit) 411, and these processed data are transmitted as illustrated through the control bus lines 412, 413, 414, 415, 416, 417, 418, and 419.

Further, in the present invention, a time control unit 421 (for example, generates a control signal by using a clock from a wave clock) is provided inside the arithmetic operation circuit unit 411, so that all the steps 301 to 309 can be accurately controlled.

Further, in the present invention, as the magnet unit used in the magnetron sputtering, a permanent magnet commonly used can be used.

Further, when the magnetron sputtering is performed upon stopping the movement of the tray, a target having an area slightly larger than the substrate 12 is prepared, and a plurality of magnet units are disposed on the rear surface of the target spaced at appropriate intervals, and they are made to perform a translation motion in the direction parallel to the target surface, so that good thickness uniformity and a high rate of target utilization can be obtained. Further, when performing the sputtering while moving the tray, with respect to the moving direction of the substrate, the target and the magnet unit having a short width as compared with a length of the substrate can be used.

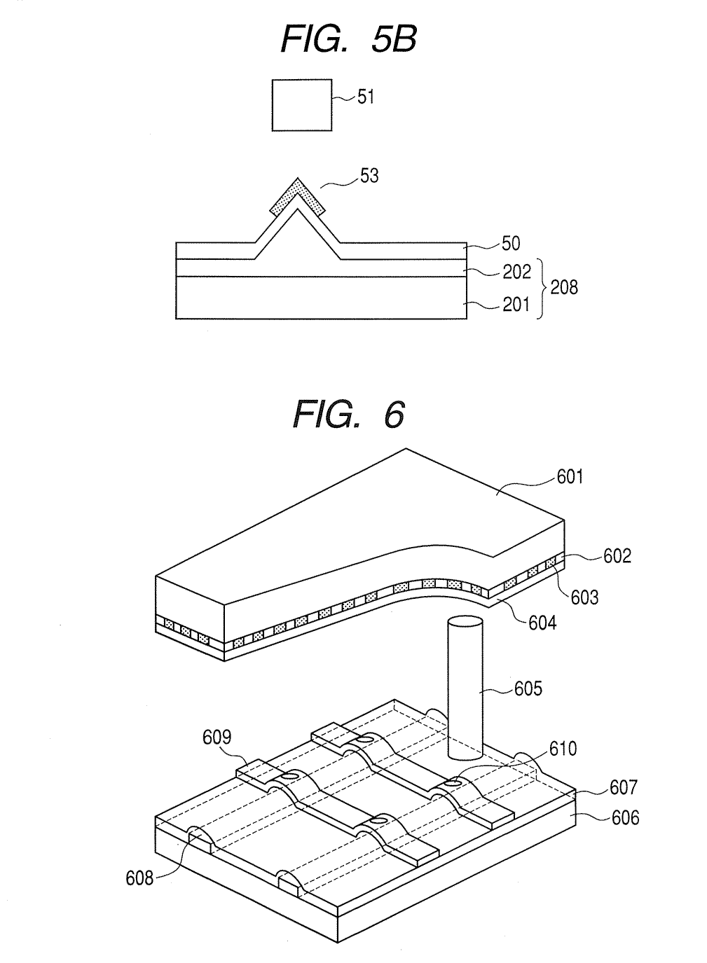

FIGS. 5A and 5B are schematic sectional views of a mask fabrication step (equivalent to the step 306 of FIG. 2) using the ink jet device. The same reference numerals as FIG. 2 in FIG. 5 denote the same members. In FIG. 5A, reference numeral 50 denotes the LaB₆ film before mask patterning, and is deposited on the entire surface of the second glass substrate 201. Reference numeral 51 denotes a head portion of an ink jet device, and reference numeral 52 denotes a droplet ejected from the ink jet head 51, which contains a material for forming the mask material. Reference numeral 53 in FIG. 5B denotes a mask formed by the ejection of the droplet 52, which can mask the LaB₆ thin film 203. The droplet 52 at this time can be made a plurality of droplets. Next, the step 307 is executed, thereby the electron emitting device illustrated in FIG. 2 can be fabricated.

FIG. 6 is a schematic perspective view of the electron emitting device of one example obtained by the manufacturing method of the present invention. In FIG. 6, reference numeral 601 denotes a glass support substrate, which is a display-side substrate of the side from which the display is seen. The glass support substrate 601 is a three primary color phosphor matrix made of the red phosphor, the green phosphor, and the blue phosphor. The present invention is not limited to the three primary color, and the three primary color can be further added with other colors (for example, complementary color relation colors, orange color, yellowish green color, and the like). Reference numeral 603 denotes the black matrix. Reference numeral 604 denotes a metal film of aluminum, titan, barium, and the like serving as an anode electrode, which is applied with high voltage of 300 V to 2000 V, and is set to a film thickness that transmits the electron beam. Reference numeral 605 denotes a spacer for maintaining a vacuum thickness of the vacuum chamber. The spacer 605 is fabricated by glass, ceramic, oxide metal, metal, and the like. Further, the spacer may be plate-like in addition to being column-shaped as shown in FIG. 6. Reference numeral 606 denotes a rear face substrate, which may be formed by a ceramic material, a metal oxide material, and a metal material, though a glass material is preferable. Reference numeral 607 denotes an insulator film, which is formed by silicon oxide, titan oxide, and various kinds of insulating organic resins. Reference numeral 608 denotes a scan line, and as the scan line 608, various kinds of metals (for example, aluminum, copper, silver, and the like) are used. Reference numeral 609 denotes a signal line, and as the signal line 609, various kinds of metals (for example, aluminum, copper, silver, and the like) are used. The scan line 608 and the signal line 609 are interlayer-insulated by the insulator film 607. Reference numeral 610 is a hole including the electron emitting device. The electron emitting device shown in FIG. 2 is disposed inside the hole 610. Further, inside the hole, not only the Spindt-type electron emitting device shown in FIG. 2, but also the SCE type electron emitting device may be disposed.

The scan line 608 and the signal line 609 are matrix-driven by a scan side drive circuit (not shown) and a signal side drive circuit (not shown), respectively. This matrix-drive is such that a scan signal is applied to the scan line 608 and an image signal synchronized with the scan signal is applied to the signal line 609, thereby displaying an image.

1. A manufacturing method of an electron emitting device, comprising:
a first step of preparing a first substrate disposed with phosphors and disposing the first substrate in a vacuum or reduced pressure atmosphere;
a second step of disposing an electron emitting base member on a second substrate;
a third step of depositing sputtered particles on the second substrate subjected to said second step by a sputtering method using a target having a low work function substance inside a vacuum or reduced pressure atmosphere;
a fourth step of disposing a mask for screening a first region of the second substrate including said electron emitting base member and opening a second region of the second substrate not including said electron emitting base member, in a state in which a vacuum or reduced pressure atmosphere is maintained from said third step;
a fifth step of etching a deposition of a low work function substance on the second substrate subjected to said fourth step, in a state in which the vacuum or reduced pressure atmosphere is maintained from said fourth step; and
a sixth step of making the first substrate subjected to said first step opposite the second substrate subjected to said fifth step and sealing the first substrate and the second substrate by a sealing agent to fabricate a vacuum or reduced pressure chamber, in a state in which the vacuum or reduced pressure atmosphere is maintained from said first step and said fifth step.

2. The manufacturing method according to claim 1, wherein said electron emitting base member is a Spindt-type electron emitting device.

3. The manufacturing method according to claim 1, wherein said target has a sintered body containing a boron atom (B) and a lanthanum atom (La).

4. The manufacturing method according to claim 1, wherein the deposition of said third step has a crystalline deposition containing a boron atom (B) and a lanthanum atom (La).

5. A memory medium for the manufacturing of an electron emitting device, comprising a control program for executing:
a first step of preparing a first substrate disposed with phosphors and disposing the first substrate in a vacuum or reduced pressure atmosphere;
a second step of disposing an electron emitting base member on a second substrate;
a third step of depositing sputtered particles on the second substrate subjected to said second step by a sputtering method using a target having a low work function substance inside a vacuum or reduced pressure atmosphere;
a fourth step of disposing a mask for screening a first region of the second substrate including said electron emitting base member and opening a second region of the second substrate not including said electron emitting base member, in a state in which a vacuum or reduced pressure atmosphere is maintained from said third step;
a fifth step of etching a deposition of the low work function substance on the second substrate subjected to said fourth step, in a state in which the vacuum or reduced pressure atmosphere is maintained from said fourth step; and
a sixth of making the first substrate subject to said first step opposite the second substrate subjected to said fifth step and sealing the first substrate and the second substrate by a sealing agent to fabricate a vacuum or reduced pressure chamber, in a state in which the vacuum or reduced pressure atmosphere is maintained from said first step and said fifth step.

6. The memory medium according to claim 5, wherein said electron emitting base member is a Spindt-type electron emitting device.

7. The memory medium according to claim 5, wherein said target has a sintered body containing a boron atom (B) and a lanthanum atom (La).

8. The memory medium according to claim 5, wherein the deposition of said third step has a crystalline deposition containing a boron atom (B) and a lanthanum atom (La).

9. A recording medium for the manufacturing of an electron emitting device, comprising a control program for executing:
a first step of preparing a first substrate disposed with phosphors and disposing the first substrate in a vacuum or reduced pressure atmosphere;
a second step of disposing an electron emitting base member on a second substrate;
a third step of depositing sputtered particles on the second substrate subjected to said second step by a sputtering method using a target having a low work function substance inside the vacuum or reduced pressure atmosphere;
a fourth step of disposing a mask for screening a first region of the second substrate including said electron emitting base member and opening a second region of the second substrate not including said electron emitting base member, in a state in which the vacuum or reduced pressure atmosphere is maintained from said third step;
a fifth step of etching a deposition of the low work function substance on the second substrate subjected to said fourth step, in a state in which the vacuum or reduced pressure atmosphere is maintained from said fourth step; and
a sixth step of making the first substrate subjected to said first step opposite the second substrate subjected to said fifth step and sealing the first substrate and the second substrate by a sealing agent to fabricate a vacuum or reduced pressure chamber, in a state in which the vacuum or reduced pressure atmosphere is maintained from said first step and said fifth step.

10. The recording medium according to claim 9, wherein said electron emitting base member is a Spindt-type electron emitting device.

11. The recording medium according to claim 9, wherein said target has a sintered body containing a boron atom (B) and a lanthanum atom (La).

12. The recording medium according to claim 9, wherein the deposition of said third step has a crystalline deposition containing a boron atom (B) and a lanthanum atom (La).
